(19) United States
(12) Patent Application Publication
(10) Pub. No.: US 2026/0223468 A1
(43) Pub. Date: Jul. 30, 2026

(54) IMAGE SENSING DEVICE AND IMAGE SENSING DEVICE MANUFACTURING METHOD

(71) Applicant: GCSOL Tech Co., Ltd., Taichung City (TW)

(72) Inventors: Jyun-Yi LEE, Taichung City (TW); Wei-Hung CHEN, Taichung City (TW); Pin-Yi CHEN, Taichung City (TW); Yu-Qi HUANG, Taichung City (TW)

(21) Appl. No.: 19/304,571

(22) Filed: Aug. 19, 2025

(30) Foreign Application Priority Data
Jan. 24, 2025 (TW) 114103636

(51) Int. Cl. H10F 39/00

(52) U.S. Cl. CPC H10F 39/804; H10F 39/806

(57) ABSTRACT

An image sensing device includes an image sensing structure, a die attaching layer, a first optical multilayer structure and a cover glass. The image sensing structure includes a substrate and a pixel array. The substrate includes a sensing area and a non-sensing area. The pixel array is disposed at the sensing area. The die attaching layer is disposed at the non-sensing area. The first optical multilayer structure includes a first protecting layer and a first optical film. The first protecting layer is disposed at one side of the die attaching layer and shields the pixel array, and is suitable for resisting a chemical etching. The first optical film is stocked on one side of the first protecting layer. The cover glass is disposed at the first optical multilayer structure. A light beam passes through the cover glass and the first optical multilayer structure to irradiate the pixel array.

### RELATED APPLICATIONS

This application claims priority to Taiwan Application Serial Number 114103636, filed Jan. 24, 2025, which is herein incorporated by reference.

### BACKGROUND

### Technical Field

The present disclosure relates to a sensing device and a sensing device manufacturing method. More particularly, the present disclosure relates to an image sensing device and an image sensing device manufacturing method.

### Description of Related Art

With the improvement of the technology, the camera field grows successfully, and cameras are widely used in fields such as electronic devices and vehicle driving assisting equipment.

Cameras usually include image sensing devices used to convert a light signal into an electric signal. The image sensing device may include a substrate, a pixel array, a die attaching layer, an optical multilayer structure and a cover glass. The optical multilayer structure and the die attaching layer are disposed on the cover glass in order, and a hollow area is formed on the die attaching layer by an etching process to correspond to the pixel array on the substrate.

However, in conventional techniques, as etching the optical multilayer layer, the die attaching layer and the cover glass, in addition to form the hollow area on the die attaching layer, the optical multilayer are etched and lost, and improvements thereof are required.

### SUMMARY

According to one aspect of the present disclosure, an image sensing device includes an image sensing structure, a die attaching layer, a first optical multilayer structure and a cover glass. The image sensing structure includes a substrate and a pixel array. The substrate includes a sensing area and a non-sensing area surrounding the sensing area. The pixel array is disposed at the sensing area. The die attaching layer is disposed at the non-sensing area. The first optical multilayer structure includes a first protecting layer and a first optical film. The first protecting layer is disposed at one side of the die attaching layer and shields the pixel array. The first protecting layer is suitable for resisting a chemical etching. The first optical film is stocked on one side of the first protecting layer, and the side where the first optical film is stocked faces away from the die attaching layer. The cover glass is disposed at the first optical multilayer structure. A light beam passes through the cover glass and the first optical multilayer structure to irradiate the pixel array, and the pixel array coverts the light beam into an electric signal.

According to another aspect of the present disclosure, an image sensing device manufacturing method includes a cover glass providing step, a first optical film forming step, a first protecting layer forming step, a die attaching layer forming step, an etching step and a combining step. In the cover glass providing step, a cover glass is provided. In the first optical film forming step, a first optical film is formed on a first surface of the cover glass. In the first protecting layer forming step, a first protecting layer is formed on the first optical film, and the first protecting layer is suitable for resisting a chemical etching. In the die attaching layer forming step, a die attaching layer is formed on the first protecting layer. In the etching step, the die attaching layer, the first optical film, the first protecting layer and the cover glass are processed by an etching process, and a central portion of the die attaching layer is removed by the chemical etching to form a hollow area. In the combining step, the die attaching layer, the first optical film, the first protecting layer and the cover glass cover on and are combined with an image sensing structure, the die attaching layer corresponds to a non-sensing area of the image sensing structure, and the hollow area corresponds to an sensing area of the image sensing structure.

### BRIEF DESCRIPTION OF THE DRAWINGS

The present disclosure can be more fully understood by reading the following detailed description of the embodiment, with reference made to the accompanying drawings as follows:

FIG. 1 is a three-dimensional schematic view of an image sensing device according to a first embodiment of the present disclosure.

FIG. 2 is a cross-sectional view of the image sensing device of the first embodiment of FIG. 1.

FIG. 3 is a cross-sectional view of an image sensing device according to a second embodiment of the present disclosure.

FIG. 4 is a cross-sectional view of an image sensing device according to a third embodiment of the present disclosure.

FIG. 5 is a block flow chart of an image sensing device manufacturing method according to a fourth embodiment of the present disclosure.

FIG. 6 is a relation chart of a reflectivity and a wave length of a cover set of a first comparison example before and after chemical etching.

FIG. 7 is a relation chart of a reflectivity and a wave length of a cover set of a first experimental example before and after chemical etching.

FIG. 8 is a relation chart of a transmission rate and a wave length of a cover set of a second comparison example before and after chemical etching.

FIG. 9 is a relation chart of a transmission rate and a wave length of a cover set of a second experimental example before and after chemical etching.

### DETAILED DESCRIPTION

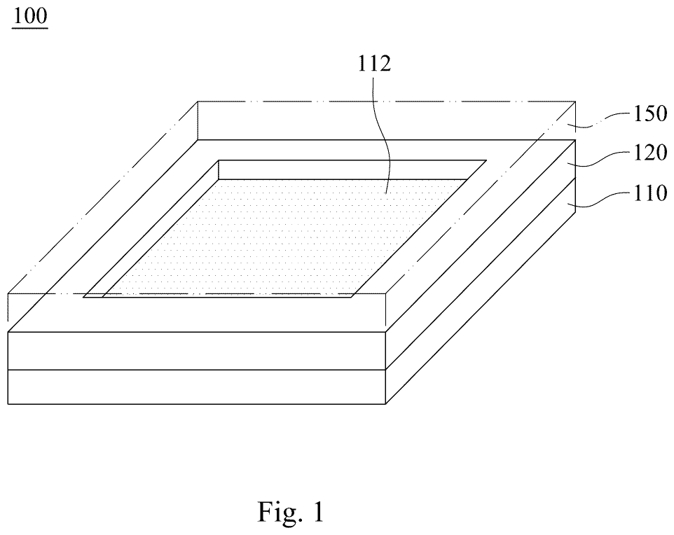

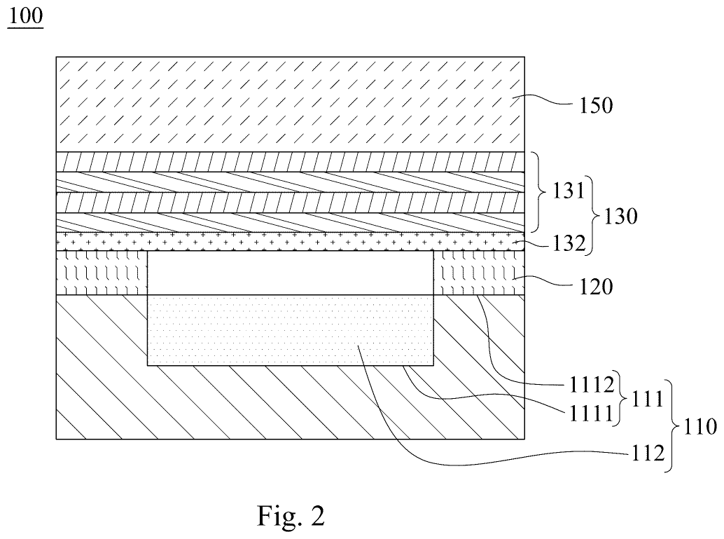

FIG. 1 is a three-dimensional schematic view of an image sensing device 100 according to a first embodiment of the present disclosure. FIG. 2 is a cross-sectional view of the image sensing device 100 of the first embodiment of FIG. 1. The image sensing structure 110 includes an image sensing structure 110, a die attaching layer 120, a first optical multilayer structure 130 and a cover glass 150. The image sensing structure 110 includes a substrate 111 and a pixel array 112. The substrate 111 includes a sensing area 1111 and a non-sensing area 1112 surrounding the sensing area 1111. The pixel array 112 is disposed at the sensing area 1111. The die attaching layer 120 is disposed at the non-sensing area 1112. The first optical multilayer structure 130 includes a first protecting layer 132 and a first optical film 131. The first protecting layer 132 is disposed at one side of the die attaching layer 120 and shields the pixel array 112. The first protecting layer 132 is suitable for resisting a chemical etching. The first optical film 131 is stocked on one side of the first protecting layer 132, and the side where the first optical film 131 is stocked faces away from the die attaching layer 120. The cover glass 150 is disposed at the first optical multilayer structure 130. A light beam passes through the cover glass 150 and the first optical multilayer structure 130 to irradiate the pixel array 112, and the pixel array 112 coverts the light beam into an electric signal.

Therefore, with the configuration of the first protecting layer 132 to resist the chemical etching, the chemical etching may not affect the first optical film 131, and the optical lost caused thereby may be prevented.

Precisely, the substrate 111 is a rectangular block, the sensing area 1111 represents the area where the pixel array 112 is disposed, and the non-sensing area 1112 represents the area where the pixel array 112 is not disposed. In the first embodiment, a cavity (not labeled) is formed on a surface of the substrate 111, the cavity may accommodate the pixel array 112 and is served as the sensing area 1111, and other flat portions of the surface may be served as the non-sensing area 1112 and surrounds the sensing area 1111. The non-sensing area 1112 may be provided for the die attaching layer 120 to be disposed thereon, and the first protecting layer 132, the first optical film 131 and the cover glass 150 may be disposed on the die attaching layer 120 in order. Therefore, the optical characteristics of the image sensing device 100 may be adjusted by the first optical film 131, and the optical characteristics of the image sensing device 100 will not be affected owing to corrosion of the first optical film 131 caused by the chemical etching because the first protecting layer 132 can resist the chemical etching. The light beam may be converted into the electric signal by the pixel array 112, and the electric signal is sent to a processor (not labeled) for later processing.

The first optical film 131 may include a first film layer (not labeled) and a second film layer (not labeled) arranged staggeredly. The first film layer may be made of materials with a high refractive index, such as TiO₂, Nb₂O₅, HfO₂, Ta₂O₅, ZrO₂, SiN and so on. The second film layer may be made of materials with a low refractive index, such as SiO₂, Al₂O₃, MgF₂ and so on. In the first embodiment, the first film layer is made of Nb₂O₅, and the second film layer is made of SiO₂. The first optical film 131 includes two first film layers and two second film layers arranged staggeredly. In other embodiments, a number of the first film layers and a number of the second film layers are plural, and the first film layers and the second film layers arranged staggeredly.

The first protecting layer 132 may be made of materials containing SiN, ZrO₂, HfO₂ or Ta₂O₅, and a multi-component nitride or a multi-component oxide is doped in the first protecting layer 132. Precisely, the material of the first protecting layer 132 has a high refractive index and can resist the chemical etching. The material thereof may include different components, SiON, ZrSiO₄ and TaSiO may for example be used based on the aforementioned components, and thus has an etching selectively higher than the first optical film 131 and an etching rate lower than the first optical film 131. In the first embodiment, a thickness of the first protecting layer 132 may be larger than or equal to 1 nm and smaller than or equal to 12 nm. With the limitation of the thickness, the optical effect caused by the high refractive index is lowered.

As a wave length of the light beam is larger than or equal to 400 nm and smaller than or equal to 900 nm, a refractive index of the first protecting layer 132 is larger than or equal to 1.7 and smaller than or equal to 3, and an extinction coefficient of the first protecting layer 132 is smaller than 0.01 or smaller than 0.001. As the wave length of the light beam is larger than or equal to 400 nm and smaller than or equal to 850 nm, an average reflectivity of the cover glass 150 and the first optical multilayer structure 130 is smaller than 3%. As the wave length of the light beam is larger than or equal to 400 nm and smaller than or equal to 700 nm, the average reflectivity of the cover glass 150 and the first optical multilayer structure 130 is smaller than 0.5%.

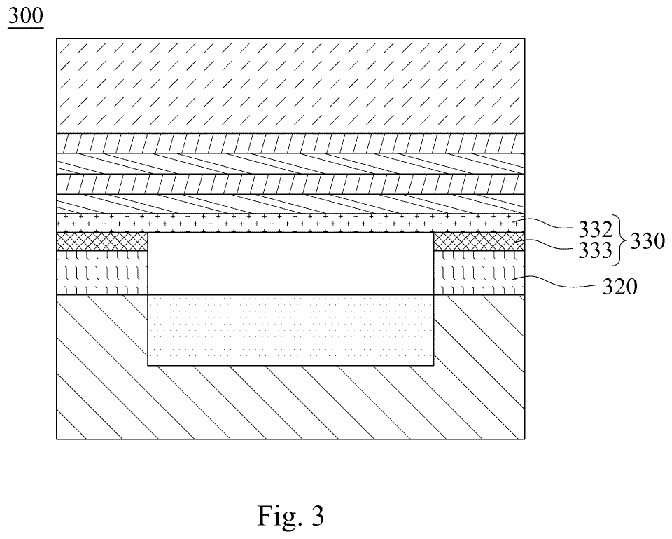

FIG. 3 is a cross-sectional view of an image sensing device 300 according to a second embodiment of the present disclosure. The image sensing device 300 of the second embodiment is similar to the image sensing device 100 of the first embodiment, and only the differences are described hereinafter. The first optical multilayer structure 330 further includes a surface modification film 333 disposed between a die attaching layer 320 and a first protecting layer 332, and a contact angle of the surface modification film 333 is smaller than a contact angle of the first protecting layer 332. To be more specific, the contact angle of the first protecting layer 332 is between 30 degrees to 80 degrees or larger than 40 degrees. The contact angle of the surface modification film 333 is smaller than or equal to 40 degrees or smaller than or equal to 30 degrees, and therefore the first optical multilayer structure 330 is allowed to combine with the die attaching layer 320 by the surface modification film 333 having the smaller contact angle. In addition, a shape of the surface modification film 333 corresponds to a shape of the die attaching layer 320, and that the optical characteristics of the first optical multilayer structure 330 is affected by the area being not shielded by the die attaching layer 320 is prevented. In the second embodiment, the surface modification film 333 may be made of SiO₂, but the present disclosure is not limited thereto.

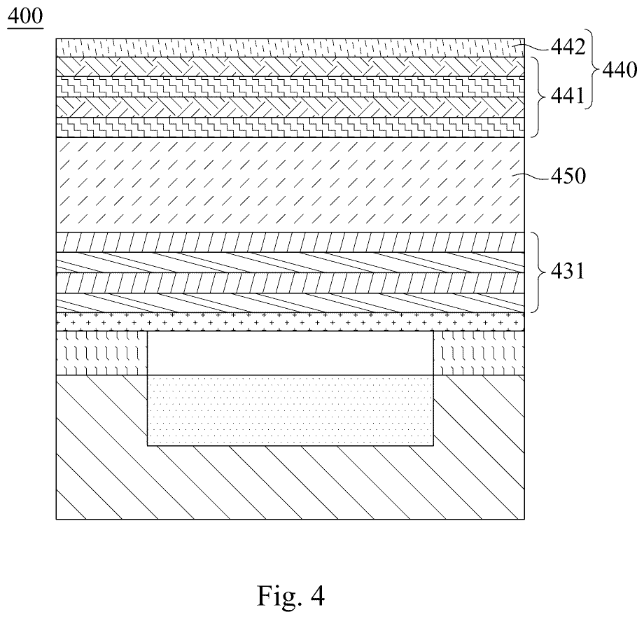

FIG. 4 is a cross-sectional view of an image sensing device 400 according to a third embodiment of the present disclosure. The image sensing device 400 of the third embodiment is similar to the image sensing device 100 of the first embodiment, and only the differences are described hereinafter. The image sensing device 400 may further include a second optical multilayer structure 440 disposed at one side of a cover glass 450 and including a second optical film 441 and a second protecting layer 442. The side where the second optical multilayer structure 440 is disposed faces away from the first optical film 431, and the second optical film 441 is located between the cover glass 450 and the second protecting layer 442. In other words, the second protecting layer 442 is located outmost. The configurations of the second optical film 441 and the second protecting layer 442 are respectively identical to the first optical film 431 and the first protecting layer. With the second protecting layer 442 to resist the acidic or alkaline environment, the image sensing device 400 may be used in a harsh environment.

It is noted that, the first optical multilayer structure 130, 330, the second optical multilayer structure 440 and the cover glass 150, 450 are for illustration, and the real thicknesses thereof are not shown.

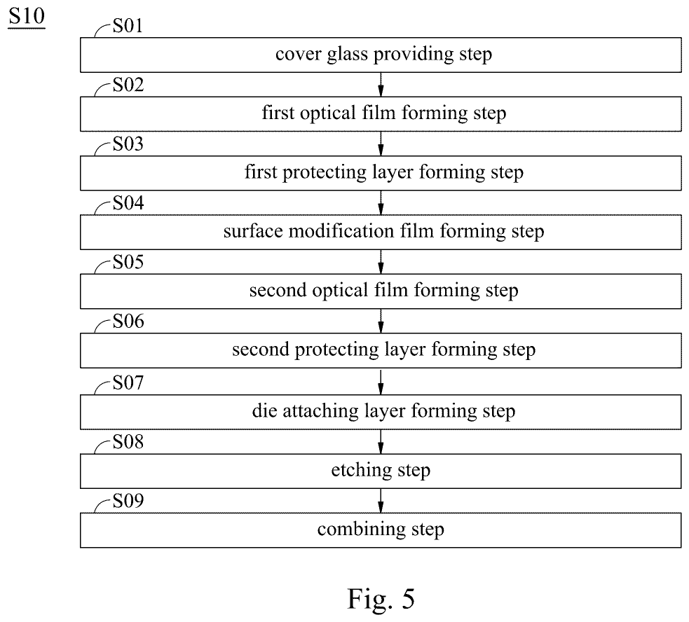

FIG. 5 is a block flow chart of an image sensing device manufacturing method S10 according to a fourth embodiment of the present disclosure. The image sensing device manufacturing method S10 includes a cover glass providing step S01, a first optical film forming step S02, a first protecting layer forming step S03, a die attaching layer forming step S07, an etching step S08 and a combining step S09.

In the cover glass providing step S01, a cover glass is provided. In the first optical film forming step S02, a first optical film is formed on a first surface of the cover glass. In the first protecting layer forming step S03, a first protecting layer is formed on the first optical film. Therefore, a cover set may be formed.

In the die attaching layer forming step S07, a die attaching layer is formed on the first protecting layer. In the etching step S08, the cover set and the die attaching layer are processed by an etching process, and a central portion of the die attaching layer is removed by the chemical etching to form a hollow area. Precisely, after forming the die attaching layer on the first protecting layer, a photoresist is coated on the die attaching layer, and a mask pattern is transferred to the photoresist by a photolithography. Hence, the photoresist corresponding to the mask pattern remands on the die attaching layer. The shape of the mask pattern is a rectangle and corresponds to an area other than the center portion of the die attaching layer. During the chemical etching, the center portion of the die attaching layer is etched owing to not being protected by the photoresist and a hollow area is therefore formed. The protecting layer is used to prevent the first optical film from etching and thus the optical characteristics are not affected. If errors occur in the die attaching layer forming step S07 or the etching step S08, the die attaching layer may be removed by strong acid agents or strong alkaline agents, and the first protecting layer may still protect the first optical film and the cover glass. A loss of the optical characteristics (a reflectivity and a transmission rate) after reforming the die attaching layer is smaller than 0.2%.

In the combining step S09, the die attaching layer, the first optical film, the first protecting layer and the cover glass cover on and are combined with an image sensing structure, the die attaching layer corresponds to a non-sensing area of the image sensing structure, and the hollow area corresponds to a sensing area of the image sensing structure. Therefore, the image sensing device manufacturing method S10 may for example manufacture the image sensing device 100 of the first embodiment in FIG. 1.

The image sensing device manufacturing method S10 may further include a surface modification film forming step S04 performed after the first protecting layer forming step S03. A surface modification film is formed on the first protecting layer, and a contact angle of the surface modification film is smaller than a contact angle of the first protecting layer. Therefore, the image sensing device manufacturing method S10 may for example manufacture the image sensing device 300 of the second embodiment in FIG. 3.

The image sensing device manufacturing method S10 may further include a second optical film forming step S05 and a second protecting layer forming step S06. The second optical film forming step S05 is to form a second optical film on a second surface of the cover glass, and then in the second protecting layer forming step S06, a second protecting layer is formed on the second optical film. Therefore, the image sensing device manufacturing method S10 may for example manufacture the image sensing device 400 of the third embodiment in FIG. 4.

It is noted that, in the first optical film forming step S02, the first protecting layer forming step S03, the surface modification film forming step S04, the second optical film forming step S05 and the second protecting layer forming step S06, the first optical film, the first protecting layer, the surface modification film, the second optical film and the second protecting film may be formed by a plasma-assisted reactive magnetron sputtering, and a deposition rate may be ranged between 0.1 nm per second to 0.2 nm per second. To be more specific, argon flows into a cathode region and is dissociated owing to an electric field and a magnet field, thus the argon plasma hits a target, and target elements are ejected therefrom to deposit on the cover glass, thereby forming a film with the target elements. After which, gas such as argon, oxygen, nitrogen and so on flows into a plasma reacting source area to form a reactive plasma, the reactive plasma may react with the film having the target elements to form a film that is required. For example, the target is a silicon target, a silicon film may be formed on the cover glass by the argon plasma, and the gas such as the argon, oxygen, nitrogen and so on may be used to form the reactive plasma for reacting with the silicon film, and a SiO₂ film may be formed.

### Experimental Example

Table 1 shows materials and thicknesses of first optical multilayer structures of a first experimental example, a first comparison example, a second experimental example and a second comparison example. A number of the layers and materials of the first optical film of the first experimental example are respectively identical to a number of the layers and materials of the first optical film of the first comparison example. A number of the layers and materials of the first optical film of the second experimental example are respectively identical to a number of the layers and materials of the first optical film of the second comparison example. Each of the first experimental example and the second experimental example includes the first protecting layer of the present disclosure, while each of the first comparison example and the second comparison example does not have the first protecting layer but have a thinker second film layer that is nearest the die attaching layer.

TABLE 1

| | thickness of | thickness of | thickness of | thickness of |
|---|---|---|---|---|
| | the first | the first | the second | the second |
| | comparison | experimental | comparison | experimental |
| | example | example | example | example |
| material | (nm) | (nm) | (nm) | (nm) |
| Nb₂O₅ | 11.8 | 11.8 | 5.9 | 5.05 |
| SiO₂ | 34.4 | 34.4 | 64.7 | 69.29 |
| Nb₂O₅ | 110.3 | 110.3 | 15.1 | 13.54 |
| SiO₂ | 84.7 | 72.1 | 62.9 | 66.28 |
| Nb₂O₅ | | | 13.71 | 12.24 |
| SiO₂ | | | 220.63 | 228.96 |
| Nb₂O₅ | | | 23.79 | 22.49 |
| SiO₂ | | | 24.06 | 27.24 |
| Nb₂O₅ | | | 71.6 | 68.01 |
| SiO₂ | | | 24.03 | 23.1 |
| Nb₂O₅ | | | 21.8 | 30.68 |
| SiO₂ | | | 114.33 | 69.14 |
| Nb₂O₅ | | | 11.64 | 19.37 |
| SiO₂ | | | 42.38 | 44.34 |
| Nb₂O₅ | | | 116.34 | 123.5 |
| SiO₂ | | | 90.46 | 60.48 |
| SiN | | 5 | | |
| Ta₂O₅ | | | | 10 |

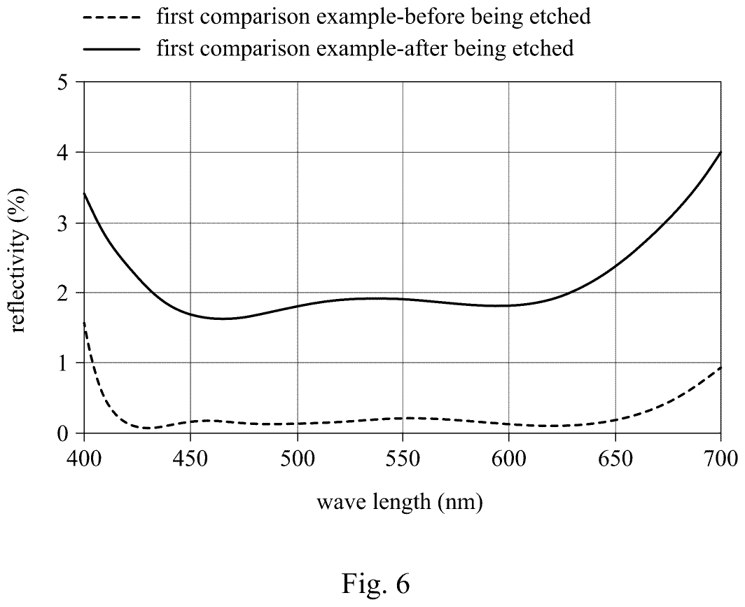

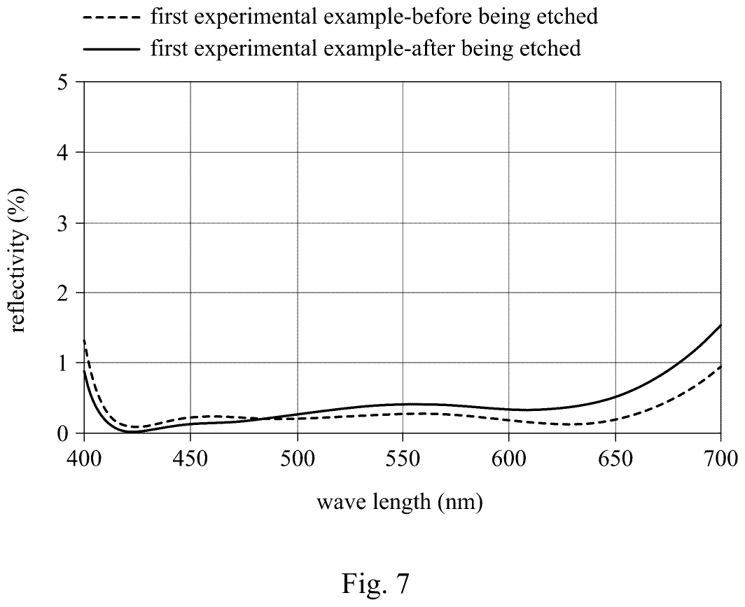

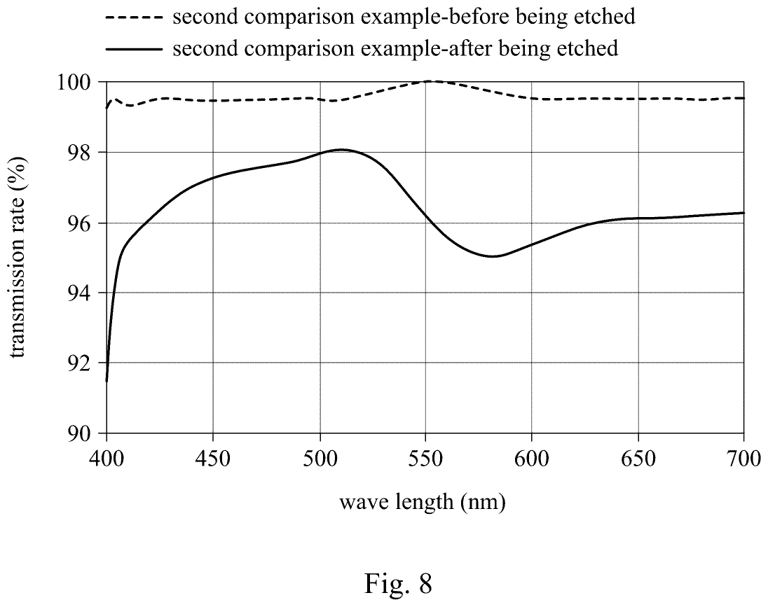

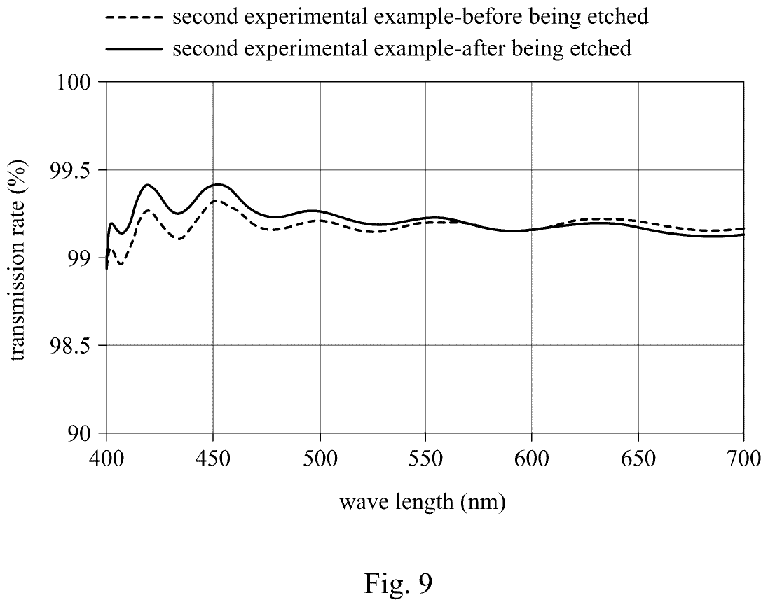

FIG. 6 is a relation chart of a reflectivity and a wave length of a cover set of the first comparison example before and after chemical etching. FIG. 7 is a relation chart of a reflectivity and a wave length of a cover set of the first experimental example before and after chemical etching. FIG. 8 is a relation chart of a transmission rate and a wave length of a cover set of the second comparison example before and after chemical etching. FIG. 9 is a relation chart of a transmission rate and a wave length of a cover set of the second experimental example before and after chemical etching. It is known from the first comparison example in FIG. 6 and the second comparison example in FIG. 8, when there is no first protecting layer (SiN or Ta₂O₅), the optical characteristic is lost owing to the chemical etching, especially the reflectivity of the first comparison example being increased and the transmission rate of the second comparison example being lowered. Moreover, it is known from the first experimental example in FIG. 7 and the second experimental example in FIG. 9, with the first protecting layer (SiN or Ta₂O₅), the reflectivity and the transmission rate are only slightly affected. Therefore, the structure of the present disclosure can prevent the first optical film from being affected by etching, and the optical loss is decreased.

To sum up, the present disclosure includes the following advantages. First, with the configuration of the first protecting layer, the optical characteristics of the image sensing device will not be affected by the chemical etching. Second, with the configuration of the second protecting layer, the image sensing device may be used in a harsh environment. Third, with the configuration of the surface modification film, the first optical multilayer film structure may be combined with the die attaching layer easier.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An image sensing device, comprising:
an image sensing structure, comprising:
a substrate comprising a sensing area and a non-sensing area surrounding the sensing area; and
a pixel array disposed at the sensing area;
a die attaching layer disposed at the non-sensing area;
a first optical multilayer structure, comprising:
a first protecting layer disposed at one side of the die attaching layer and shielding the pixel array, the first protecting layer being suitable for resisting a chemical etching; and
a first optical film stocked on one side of the first protecting layer, wherein the side where the first optical film is stocked faces away from the die attaching layer; and
a cover glass disposed at the first optical multilayer structure;
wherein a light beam passes through the cover glass and the first optical multilayer structure to irradiate the pixel array, and the pixel array coverts the light beam into an electric signal.

2. The image sensing device of claim 1, further comprising a second optical multilayer structure disposed at one side of the cover glass and comprising a second optical film and a second protecting layer, wherein the side where the second optical multilayer structure is disposed faces away from the first optical film, and the second optical film is located between the cover glass and the second protecting layer.

3. The image sensing device of claim 1, wherein a material of the first protecting layer comprises SiN, ZrO₂, HfO₂ or Ta₂O₅.

4. The image sensing device of claim 3, wherein a multi-component nitride or a multi-component oxide is doped in the first protecting layer.

5. The image sensing device of claim 1, wherein the first optical multilayer structure further comprises a surface modification film disposed between the die attaching layer and the first protecting layer, and a contact angle of the surface modification film is smaller than a contact angle of the first protecting layer.

6. The image sensing device of claim 1, wherein a thickness of the first protecting layer is larger than or equal to 1 nm and smaller than or equal to 12 nm.

7. The image sensing device of claim 1, wherein as a wave length of the light beam is larger than or equal to 400 nm and smaller than or equal to 900 nm, a refractive index of the first protecting layer is larger than or equal to 1.7 and smaller than or equal to 3, and an extinction coefficient of the first protecting layer is smaller than 0.01.

8. The image sensing device of claim 1, wherein as a wave length of the light beam is larger than or equal to 400 nm and smaller than or equal to 850 nm, an average reflectivity of the cover glass and the first optical multilayer structure is smaller than 3%.

9. The image sensing device of claim 1, wherein as a wave length of the light beam is larger than or equal to 400 nm and smaller than or equal to 700 nm, an average reflectivity of the cover glass and the first optical multilayer structure is smaller than 0.5%.

10. The image sensing device of claim 1, wherein the first optical multilayer structure is formed by a plasma-assisted reactive magnetron sputtering.

11. An image sensing device manufacturing method, comprising:
a cover glass providing step, wherein a cover glass is provided;
a first optical film forming step, wherein a first optical film is formed on a first surface of the cover glass;
a first protecting layer forming step, wherein a first protecting layer is formed on the first optical film, and the first protecting layer is suitable for resisting a chemical etching;
a die attaching layer forming step, wherein a die attaching layer is formed on the first protecting layer;
an etching step, wherein the die attaching layer, the first optical film, the first protecting layer and the cover glass are processed by an etching process, and a central portion of the die attaching layer is removed by the chemical etching to form a hollow area; and
a combining step, wherein the die attaching layer, the first optical film, the first protecting layer and the cover glass cover on and are combined with an image sensing structure, the die attaching layer corresponds to a non-sensing area of the image sensing structure, and the hollow area corresponds to an sensing area of the image sensing structure.

12. The image sensing device manufacturing method of claim 11, further comprising a second optical film forming step and a second protecting layer forming step, the second optical film forming step is performed after the first protecting layer forming step and is to form a second optical film on a second surface of the cover glass, and then in the second protecting layer forming step, a second protecting layer is formed on the second optical film.

13. The image sensing device manufacturing method of claim 11, wherein in the first protecting layer forming step, a material of the first protecting layer comprises SiN, ZrO₂, HfO₂ or Ta₂O₅.

14. The image sensing device manufacturing method of claim 13, wherein a multi-component nitride or a multi-component oxide is doped in the first protecting layer.

15. The image sensing device manufacturing method of claim 11, further comprising a surface modification film forming step performed after the first protecting layer forming step, wherein a surface modification film is formed on the first protecting layer, and a contact angle of the surface modification film is smaller than a contact angle of the first protecting layer.

16. The image sensing device manufacturing method of claim 11, wherein in the first protecting layer forming step, a thickness of the first protecting layer is larger than or equal to 1 nm and smaller than or equal to 12 nm.

17. The image sensing device manufacturing method of claim 11, wherein in the first optical film forming step and the first protecting layer forming step, the first optical film and the first protecting layer are formed by a plasma-assisted reactive magnetron sputtering.
